(19) United States
(12) Patent Application Publication
(10) Pub. No.: US 2026/0282951 A1
(43) Pub. Date: Sep. 17, 2026

(54) MODULAR COAXIAL BRIDGE

(71) Applicant: Applied Materials, Inc., Santa Clara, CA (US)

(72) Inventor: Seann William AYERS, Phoenix, AZ (US)

(73) Assignee: Applied Materials, Inc., Santa Clara, CA (US)

(21) Appl. No.: 19/078,220

(22) Filed: Mar. 12, 2025

(51) Int. Cl. H01L 23/538; H01L 23/00; H01L 23/498

(52) U.S. Cl. CPC H10W 70/611; H10W 70/635; H10W 90/401; H10W 90/724

(57) ABSTRACT

In modern advanced electronic packages, such as 2.5D packages, very high communication bandwidth is required to meet the demands of modern artificial intelligence workloads. However, traditional 2.5 D interconnects use 1-2 μm-micron wide copper traces that are typically implemented in a silicon dioxide dielectric material as individual strip lines or a microstrip of individual transmission lines. These existing copper transmission lines are unable to transmit signals at high frequencies without introducing a significant bit error rate. The modular coaxial bridge described herein can replace these traditional interconnect techniques by the densely packaging a large number of individual coaxial transmission lines into a single modular unit. This coaxial bridge greatly reduces the insertion loss transmissions between dies on an interposer, resulting in transmission speeds greater than 100 Gbps.

### TECHNICAL FIELD

This disclosure generally relates to communication between dies in electronic assembly. More specifically, this disclosure describes a modular embedded coaxial bridge between dies in a 2.5D package.

### BACKGROUND

A 2.5D package for integrated circuits is an advanced semiconductor packaging technology that allows for high-bandwidth communication between multiple chips or chiplets within a single package. One of the key features of a 2.5D package is the use of an interposer, which is a passive or active substrate (e.g., silicon, organic, glass, etc.) that provides dense interconnections between the various integrated circuits. Unlike traditional printed circuit board (PCB) packaging, a 2.5 D package places the interposer between the dies and the package substrate. The interposer then routes electrical signals between the dies, resulting in a much lower level of power consumption. Importantly, the interposer enables integration of different types of integrated circuits, such as core processors, graphic processors, memory chips, accelerators, and so forth, within the same package. These chips can also be heterogeneous in terms of the associated semiconductor manufacturing processes (a 5 nm CPU die combined with a 7 nm CPU die). The shorter interconnect pathways compared to traditional PCB-based designs improve bandwidth, reduce signal delays, and reduce power consumption. The dense interconnect also allows for wide data buses, which may be advantageous for artificial intelligence and high-performance computing applications.

### BRIEF SUMMARY

In some embodiments, an electronic assembly may include an interposer; a first die mounted on the interposer; a second die in the electronic assembly; and a coaxial bridge that conductively couples the first die and the second die.

In some embodiments, a coaxial bridge for a 2.5D package may include a plurality of coaxial transmission lines, where each of the plurality of coaxial transmission lines may include a conductive core; a dielectric material encasing the conductive core; a conductive coaxial enclosure encasing the dielectric material; and a pair of hybrid bonding interfaces that are conductively coupled to ends of the conductive core. The plurality of coaxial transmission lines may be packaged together in a single modular unit.

In some embodiments, a method of transmitting signals between dies in a 2.5D package may include transmitting a signal from a first die mounted to an interposer in the 2.5D package; transmitting the signal from the first die through a coaxial bridge that electrically connects the first die to a second die mounted to the interposer in the 2.5 D package; and receiving the signal from the coaxial bridge at the second die.

In any embodiments, any and all of the following features may be implemented in any combination and without limitation. The second die may be mounted on the interposer adjacent to the first die, and the coaxial bridge may be oriented horizontally in the electronic assembly. The second die may be mounted vertically above the first die in the electronic assembly, and the coaxial bridge may be oriented vertically in the electronic assembly. The coaxial bridge may be mounted to the interposer. The coaxial bridge may be mounted to a surface of the interposer. The interposer may include a cavity that extends between the first die and the second die and below a surface of the interposer, and the coaxial bridge may be mounted in the cavity. The coaxial bridge may be connected directly to pads on bottom surfaces of the first die and the second die through a hybrid bonding interface. The coaxial bridge may be connected directly to pads on a surface of the interposer. The coaxial bridge may include a rigid, modular structure having a plurality of individual coaxial transmission lines. The coaxial bridge may include a length of between about 5 mm and about 15 mm. Each conductive core may be between about 0.5 μm and about 1.5 μm wide. A pitch of the plurality of coaxial transmission lines may be between about 6 μm and about 16 μm. Each of the plurality of coaxial transmission lines may have a width of between about 2.5 μm and about 7.5 μm. The conductive core may include a metal, the dielectric material may include a material with a dielectric constant less than about 2.5 at 1 MHz, and the conductive coaxial enclosure may include a metal. A transmission rate through a single coaxial transmission line in the coaxial bridge may be greater than about 75 Gbps. A transmission rate through the coaxial bridge may be greater than or about 50 Tbps/mm of space along an edge of the first die. The signal may include contents of a memory location in a high-bandwidth memory of the second die. The coaxial bridge may include greater than about 100 channels per millimeter of space along an edge of the first die.

### BRIEF DESCRIPTION OF THE DRAWINGS

A further understanding of the nature and advantages of various embodiments may be realized by reference to the remaining portions of the specification and the drawings, wherein like reference numerals are used throughout the several drawings to refer to similar components. In some instances, a sub-label is associated with a reference numeral to denote one of multiple similar components. When reference is made to a reference numeral without specification to an existing sub-label, it is intended to refer to all such multiple similar components.

FIG. 1 illustrates an electronic assembly configured in a 2.5D package, according to some embodiments.

FIG. 2 illustrates an example of a modular coaxial bridge, according to some embodiments.

FIG. 3A illustrates an isometric view of ends of a plurality of coaxial transmission lines in the coaxial bridge, according to some embodiments.

FIG. 3B illustrates a cross-sectional side view one of the coaxial transmission lines, according to some embodiments.

FIGS. 4A-4C illustrate block diagrams of how a coaxial bridge may be used in an electronic assembly to electrically connect IC dies, according to some embodiments.

FIG. 5 illustrates a configuration where the coaxial bridge sits on top of the interposer, according to some embodiments.

FIG. 6 illustrates a configuration where the coaxial bridge may be inverted on the interposer, according to some embodiments.

FIG. 7 illustrates a configuration where the coaxial bridge is mounted on a top side of the dies, according to some embodiments.

FIG. 8 illustrates a method of transmitting signals between dies in a 2.5 D package, according to some embodiments.

FIG. 9 illustrates a graph that illustrates a bit error rate for a traditional RDL in an interposer.

FIG. 10 illustrates a graph showing the same signal transmission using a coaxial bridge, according to some embodiments.

FIG. 11 illustrates a graph illustrating a comparison of the insertion loss at various frequencies, according to some embodiments.

### DETAILED DESCRIPTION

In modern advanced electronic packages, such as 2.5D packages, very high communication bandwidth is required to meet the demands of modern artificial intelligence workloads. However, traditional 2.5 D interconnects use 1-2 μm-micron wide copper traces that are typically implemented in a silicon dioxide dielectric material as individual strip lines or a microstrip of individual transmission lines. These existing copper transmission lines are unable to transmit signals at high frequencies without introducing a significant bit error rate. The modular coaxial bridge described herein can replace these traditional interconnect techniques by the densely packaging a large number of individual coaxial transmission lines into a single modular unit. This coaxial bridge greatly reduces the insertion loss transmissions between dies on an interposer, resulting in transmission speeds greater than 100 Gbps.

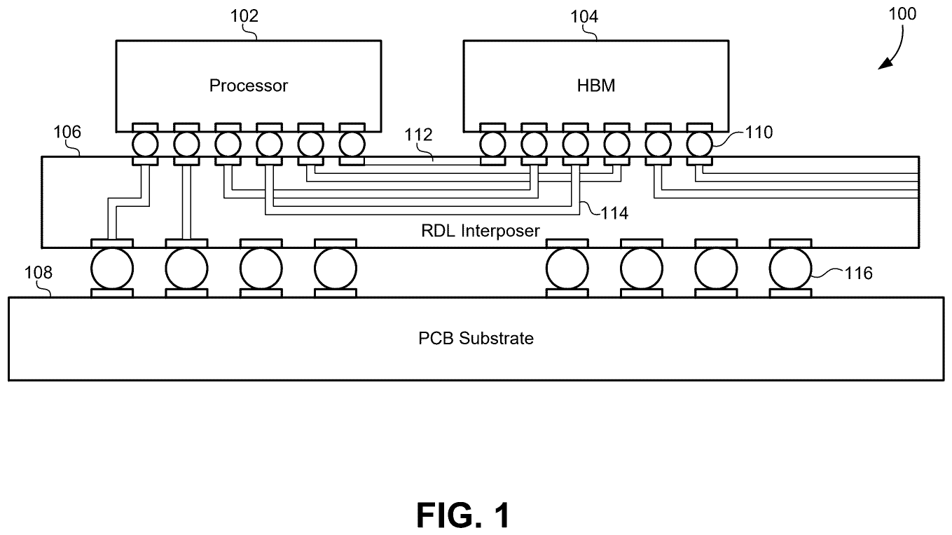

FIG. 1 illustrates an electronic assembly 100 configured in a 2.5D package, according to some embodiments. Conventional electronic packaging methods often rely on two-dimensional (2D) or three-dimensional (3D) integration techniques. However, these 2D/3D techniques may pose challenges in terms of the interconnect density within the substrates that connects various integrated circuit (IC) dies. For example, routing topologies, signal integrity, and thermal management involve difficult technical problems in existing 2D/3D packages. A 2.5D package addresses these technical problems by incorporating an interposer to facilitate communication between the IC dies.

The electronic assembly 100 may be configured as a 2.5D package that includes an interposer 106. The interposer 106 may be referred to as a redistribution layer (RDL) interposer that incorporates one or more redistribution layers for signal routing and power delivery. The interposer 106 may be fabricated from a number of different materials, including silicon, organic materials, glass, and/or the like. The interposer 106 may primarily serve as an intermediate layer between the IC dies and a printed circuit board (PCB) substrate 108, enabling high-bandwidth, low-latency communication while also reducing interconnect complexity.

The electronic assembly 100 may include any type of IC dies mounted to the interposer 106. The electronic assembly 100 includes example IC dies, such as a processor 102 and a high-bandwidth memory (HBM) 104. An HBM is a type of memory that may be stacked vertically in 2.5D/3D configurations, which allows for wider memory interfaces and higher data transfer rates than traditional memories. The HBM 104 may represent one of these HBM stacks comprising multiple DRAM chips connected through TSVs or other vertical interfaces. The processor 102 may include a high-bandwidth interface (e.g., a coherent interface, an advanced high-performance bus (AHB), etc.) designed to provide high-speed communication channels between the processor 102 and the HBM 104. Therefore, the signals being passed back and forth between the processor and the HBM may include contents of memory locations, memory addresses, and other memory communications. Note that the processor 102 and the HBM 104 are illustrated only by way of example and are not meant to be limiting. In other embodiments, additional IC dies may also be mounted to the interposer 106 without limitation, including systems-on-a-chip (SoCs), microcontrollers, communication ICs, accelerators, and so forth.

The electronic assembly 100 may also include a PCB substrate 108 that acts as a foundational support and electrical interface for the electronic assembly 100. The PCB substrate 108 may differ from the interposer 106 in function and/or material. For example, the PCB substrate 108 may typically be manufactured from PCB materials, such as fiberglass-reinforced epoxy (e.g., FR4) or other organic materials. The PCB substrate 108 may also provide mechanical support for the electronic assembly 100 and may be integrated into a larger system-interface. In contrast, the interposer 106 may feature finer routing geometries and redistribution layers than are typically found in PCB materials and may be used as a transitional RDL between the IC dies and the PCB substrate 108. The PCB substrate 108 may be connected to the interposer 106 using solder bumps or ball grid arrays (BGAs) 116 to provide both a mechanical and an electrical coupling between the two components. Some embodiments may also include underfill materials (e.g., epoxy) to enhance the reliability and reduce mechanical stress induced by thermal expansion between the PCB substrate 108 and the interposer 106.

In some embodiments, the electronic assembly 100 may include a specific type of 2.5 D packaging referred to as a Chip-on-Wafer-on-Substrate (CoWoS) architecture, a technology developed for high-performance computing applications. The CoWoS architecture utilizes a silicon interposer for the interposer 106 with through-silicon vias (TSVs) to achieve ultra-high-density interconnects between high-speed systems, such as the processor 102 and the HBM 104. The RDL in the interposer 106 along with optional TSVs may connect these components using surface traces 112 and/or internal traces 114. The interposer 106 may include the RDL and/or back-end-of-line (BEOL) copper interconnects that are embedded in, for example, a silicon dioxide interposer material. For example, the copper interconnects may form strip line, microstrip, or other similar connections.

While the CoWoS architecture is particularly advantageous for high-speed memory/processor transmissions another artificial intelligence (AI) applications, the increasing speeds required for these applications is beginning to cause signal integrity issues in these high-speed communications. Specifically, a technical problem exists where high-speed signals suffer from high attenuation on the copper traces in the interposer. For example, typical copper traces are between 1 μm and 2 μm wide and limited to about 1 mm in length between the ICs. At high frequencies, the bulk of the conductor losses believed to be the result of the skin effect. The skin effect is an electrical phenomenon that occurs at high frequencies in copper traces where the alternating current tends to flow primarily near the surface of the conductor rather than through the entire cross-sectional area. This leads to an increased resistance because the effective conducting area is reduced. This leads to what is known as an insertion loss, which refers to the attenuation a reduction in signal strength as the signal passes through the copper traces.

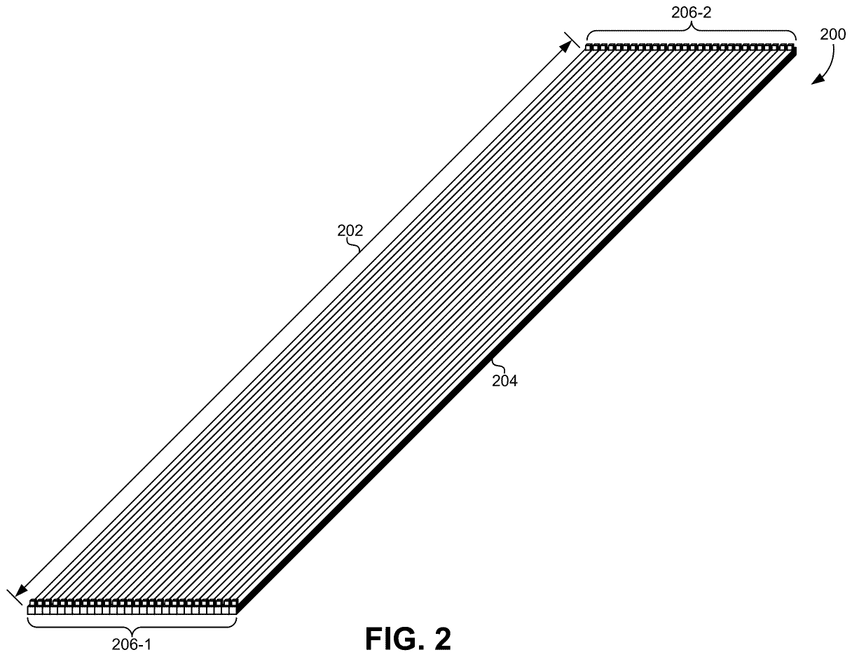

The embodiments described herein solve this technical problem by utilizing a modular coaxial bridge for communication between IC dies on an interposer in a 2.5D electronic package. FIG. 2 illustrates an example of a modular coaxial bridge 200, according to some embodiments. The coaxial bridge 200 may include a plurality of micro-sized individual coaxial transmission lines that are packaged together in a modular or singular physical unit. For example, the individual coaxial transmission lines may be embedded in a low-dielectric-constant (low-DK) material, such as Polytetrafluoroethylene (PTFE) to form a singular module. This may make the coaxial bridge 200 rigid and relatively inflexible compared to a micro wire or other type of connector. The coaxial bridge 200 may be connected as a unit to two of the IC dies on the interposer. This may distinguish the coaxial bridge 200 from a plurality of individual coaxial wires that are individually used to connect two interfaces. Since the coaxial bridge 200 is manufactured and packaged as a singular modular unit, this may also distinguish the coaxial bridge 200 from embedded coaxial communication lines that may be found formed as an integrated part of the interposer or PCB.

The coaxial bridge 200 may use thinner traces than the copper traces found in the RDL and, more importantly, may allow for much longer communication lines than the copper traces of the RDL. For example, a length 202 of the coaxial transmission lines in the coaxial bridge 200 may be between about 1 mm and about 15 mm, which is an order of magnitude longer than copper traces in the RDL would allow when communicating at high frequencies (e.g., 100 Gbps). In various embodiments, the length 202 of the coaxial bridge 200 may be between about 1 mm and about 3 mm, between about 3 mm and about 5 mm, between about 5 mm and about 7 mm, between about 7 mm and about 10 mm, between about 10 mm and about 12 mm, between about 12 mm and about 15 mm, and/or greater than about 15 mm. The length 202 may also be characterized by a combination of any of the ranges described above (e.g., between about 5 mm and about 15 mm, greater than about 5 mm, etc.). The length 202 may also include any single value in the ranges described above (e.g., about 10 mm).

The coaxial bridge 200 may include interfaces 206 on each end of the coaxial bridge 200. For example, as described in detail below, each of the individual coaxial transmission lines may be coupled with a connection point, such as a hybrid bonding interface (HBI). These HBIs may be equally spaced along each edge of the coaxial bridge 204 such that the pair of hybrid bonding interfaces 206 may be bonded to the corresponding pads or other interfaces on the IC dies mounted in the electronic assembly. Note that HBIs are used only by way of example and are not meant to be limiting. Other bonding technologies may also be compatible with the coaxial bridge 200, such as flip-chip bonding with solder bumps, microbumping, or other similar connection technologies.

An advantage of the coaxial bridge 200 is the efficient use of the “beachfront” or connection area along the edge of the IC dies in the electronic assembly. In some embodiments, the number of channels or individual coaxial transmission lines in the coaxial bridge 200 may number up to about 200 channels. Other embodiments may use multiple coaxial bridges that are divided into smaller numbers of individual coaxial transmission lines. For example, a single beachfront between two adjacent IC dies on the interposer may be connected using a single coaxial bridge or multiple coaxial bridges where the total number of channels are divided up between the multiple coaxial bridges. The number of channels may include between about 10 channels about 20 channels, between about 20 channels about 50 channels, between about 50 channels about 75 channels, between about 75 channels about 100 channels, between about 100 channels and about 125 channels, between about 125 channels and about 150 channels and about 175 channels, between about 175 channels and about 200 channels, or more, depending on the embodiment. These total channels may be all included in a single coaxial bridge, split between two coaxial bridges, or divided between three, four, five, or more coaxial bridges. Note that the number of channels is not limited since the width of the coaxial bridge 200 may be expanded to any size that may be accommodated by the beachfront length of the corresponding IC dies. Therefore, the total number of channels and corresponding total width of the coaxial bridge 200 may include any combination of the channel ranges described above (e.g. between about 75 channels and about 150 channels, greater than about 100 channels, etc.), and may also include any individual number of channels within these ranges without limitation.

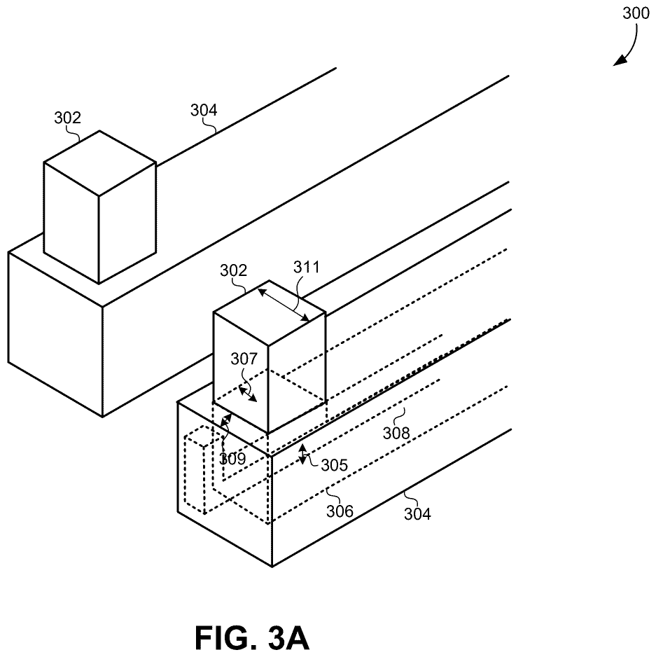

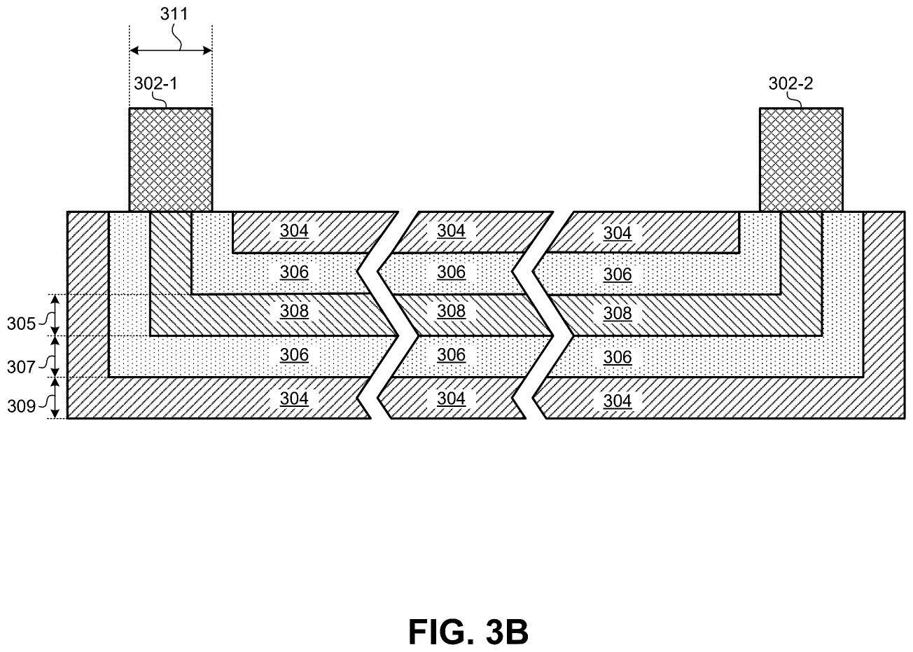

FIG. 3A illustrates an isometric view of ends of a plurality of coaxial transmission lines 300 in the coaxial bridge, according to some embodiments. FIG. 3B illustrates a cross-sectional side view one of the coaxial transmission lines, according to some embodiments. To act as a conductive carrier for signals transmitted over the coaxial bridge, each of the coaxial transmission lines may include a conductive core 308. The conductive core 308 of each of the individual coaxial transmission lines may include a conductive material, such as a metal (e.g., copper). By way of example, the conductive core 308 may be square or rectangular-shaped as depicted in FIG. 3A, or may use other geometries without limitation. The conductive core 308 may have a cross-sectional dimension 305 (width and/or height) of between about 0.5 μm and about 1.0 μm, between about 1.0 μm and about 1.5 μm, or between about 0.5 μm and about 1.5 μm (e.g., a 1.0 μm cross-sectional width).

As illustrated in FIGS. 3A-3B, the conductive core 308 may be oriented in a horizontal direction along the length of the coaxial bridge. However, at each of the ends of the modular coaxial bridge, the conductive core 308 may change direction to be vertically oriented in order to form a connection at the interfaces. For example, the vertical portion of the conductive core 308 may be exposed at each end of a coaxial transmission line. These exposed ends may each be conductively coupled to a pair of hybrid bonding interfaces 302. The hybrid bonding interfaces 302 may be formed from copper or other conductive metals.

Each of the plurality of coaxial transmission lines 300 may include a dielectric material 306 encasing the conductive core 308. The dielectric material 306 may surround and encase the conductive core 308 in order to electrically insulate the conductive core 308 from other conductive surfaces. To limit transmission losses, the dielectric material 306 should be a high-quality low-dielectric-constant material. For example, materials with a dielectric constant less than about 2.5 at 1 MHz may be used. Some embodiments may use PTFE as a dielectric material 306. The thickness 307 of the dielectric material 306 from an outer surface of the conductive core 308 to an outer surface of the of the dielectric material 306 may be between about 0.5 μm and about 1.0 μm, between about 1.0 μm and about 1.5 μm, or between about 0.5 μm and about 1.5 μm (e.g., a 3.0 μm to about 4.5 micron total cross-sectional width). The dielectric material 306 may be oriented in a horizontal direction along the length of the modular coaxial bridge and turn vertically to follow the vertical turn of the conductive core 308 at the ends of each of the coaxial transmission lines.

Each of the plurality of coaxial transmission lines 300 may include conductive coaxial enclosure 304 encasing the dielectric material 306. The conductive coaxial enclosure 304 may act as a coaxial shield to prevent any electromagnetic interference between the plurality of coaxial transmission lines 300. This minimizes or eliminates interference or crosstalk between the individual coaxial transmission lines. The coaxial enclosure 304 may surround and encase the dielectric material 306 (and consequently the conductive core 308). The thickness 309 of the coaxial enclosure 304 from an outer surface of the dielectric material 306 to an outer surface of the coaxial enclosure 304 may be between about 0.5 μm and about 1.0 μm, between about 1.0 μm and about 1.5 μm, or between about 0.5 μm and about 1.5 μm (e.g., about a 5.0 μm to about a 7.5 micron cross-section). The coaxial enclosure 304 may be oriented in a horizontal direction along the length of the modular coaxial bridge and turn vertically to follow the vertical turn of the conductive core 308 at the ends of each of the coaxial transmission lines. When connected to IC dies on the interposer, the coaxial enclosure 304 may be electrically connected to a ground signal.

The hybrid bonding interfaces 302 may be small enough such that the hybrid bonding interfaces 302 are electrically isolated from the coaxial enclosure 304 to avoid shorting the coaxial enclosure 304 to the conductive core 308. For example, the hybrid bonding interfaces may have a cross-sectional dimension 311 (width or length) of greater than about 1.0 μm and less than about 4.5 μm, depending on the dimensions of the conductive core 308 and other layers. The hybrid bonding interfaces 302 may include a flat upper surface configured to hybrid bond to a corresponding pad or metal surface on the IC die and/or interposer, depending on the configuration. The hybrid bonding interfaces 302 may be conductively coupled or directly coupled to ends of the conductive core 308.

Each of the individual coaxial transmission lines may have an overall cross-sectional dimension (width and/or height) of between about 2.5 μm and about 7.5 μm. The plurality of individual coaxial transmission lines may be packaged together in a single modular coaxial bridge. The coaxial bridge may fill any space between the coaxial transmission lines with a dielectric or other insulating material. The spacing between the coaxial transmission lines may be between about 0.5 μm and about 1.5 μm. Therefore, the pitch between the center points of the individual coaxial transmission lines in the coaxial bridge may be between about 3.0 μm and about 9.0 μm. For example, when the thicknesses of each of the individual layers in the coaxial transmission lines is about 1.0 μm, the pitch would be about 6.0 μm.

Note that the micron-scale sizes described above are dimensions that may be found in typical 2.5D electronic assemblies. However, other embodiments may be manufactured in larger sizes to accommodate different applications. For example, the dimensions may be doubled, tripled, or multiplied by any scaler factor (e.g., 10) in order to accommodate larger beachfront areas on the IC dies or to be used in other applications. Therefore, the sizes above are not meant to be limiting unless explicitly stated as such.

The coaxial bridge may be formed using a number of different manufacturing techniques. For example, additive manufacturing may be used to form the individual layers described above in each of the individual coaxial transmission lines. In other embodiments, traditional semiconductor manufacturing techniques may be used to form the layers in the coaxial bridge, such as deposition and etch processes.

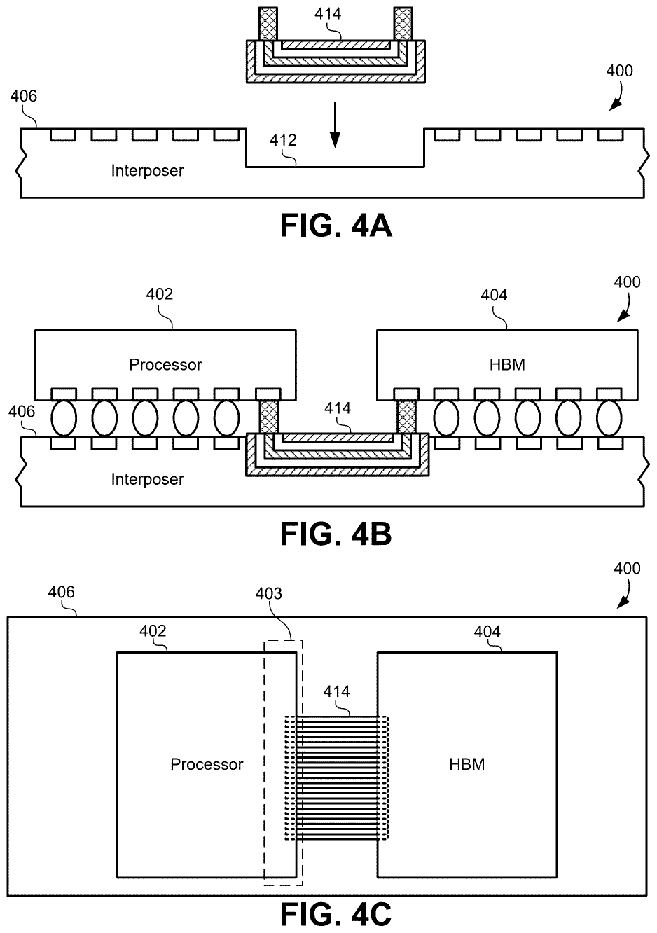

FIGS. 4A-4C illustrate block diagrams of how a coaxial bridge 414 may be used in an electronic assembly 400 to electrically connect IC dies, according to some embodiments. FIG. 4A illustrates an interposer 406 on which a plurality of IC dies may be mounted. In this configuration, a cavity 412 may be formed in the interposer 406. The cavity 412 may be routed, milled, etched, drilled, or otherwise removed from the material of the interposer 406. The dimensions of the cavity 412 may greater than or equal to the dimensions of the coaxial bridge 414. The cavity 412 may extend between locations for a first die and a second die on the interposer 406. Internal connections or redistribution layers within the interposer 406 may be designed such that forming the cavity 412 does not interfere with these internal connections.

FIG. 4B illustrates how the coaxial bridge 414 may be inserted into the cavity 412, according to some embodiments. The cavity 412 may be formed where the coaxial bridge 414 may be inserted into the cavity 412 such that at least a portion of the coaxial bridge 414 fits inside the cavity 412. For example, some embodiments may insert the entire body of the coaxial bridge 414 into the cavity 412 such that a top surface of the coaxial bridge 414 is at or below a top surface of the interposer 406. Other embodiments may allow a portion of the coaxial bridge 414 to extend above the top surface of the interposer when the depth of the cavity 412 is less than the height of the coaxial bridge 414. The coaxial bridge 414 may be secured in the cavity 412 using any adhesive method, such as epoxy.

When installed in the cavity 412, the coaxial bridge 414 may extend between locations for a first die 402 and a second die 404 to be mounted on the interposer 406. Using the hybrid bonding interfaces on the coaxial bridge 414, bottom pads of the first die 402 and the second die 404 may be bonded directly to the coaxial bridge 414. Solder bumps or other connection techniques may be used to connect to the other pads/pins on the first die 402 and the second die 404 to the interposer 406. Therefore, the depth of the cavity 412 may be sized such that the tops of the hybrid bonding interfaces make secure contact with the pads on the bottom sides of the first die 402 and the second die 404 when these dies are mounted to the interposer 406. In some embodiments, the hybrid bonding interfaces may be replaced with other connection techniques.

FIG. 4C illustrates a top view of the installed coaxial bridge 414 between the first die 402 and the second die 404. The coaxial bridge 414 is shown illustrated as a single modular unit. However, as described above, the coaxial bridge 414 may be separated into multiple individual coaxial bridges, each of which may include a plurality of coaxial transmission lines. The width of the coaxial bridge 414 may be determined based on the width of the beachfront 403 of either of the dies or the number of signals being transmitted.

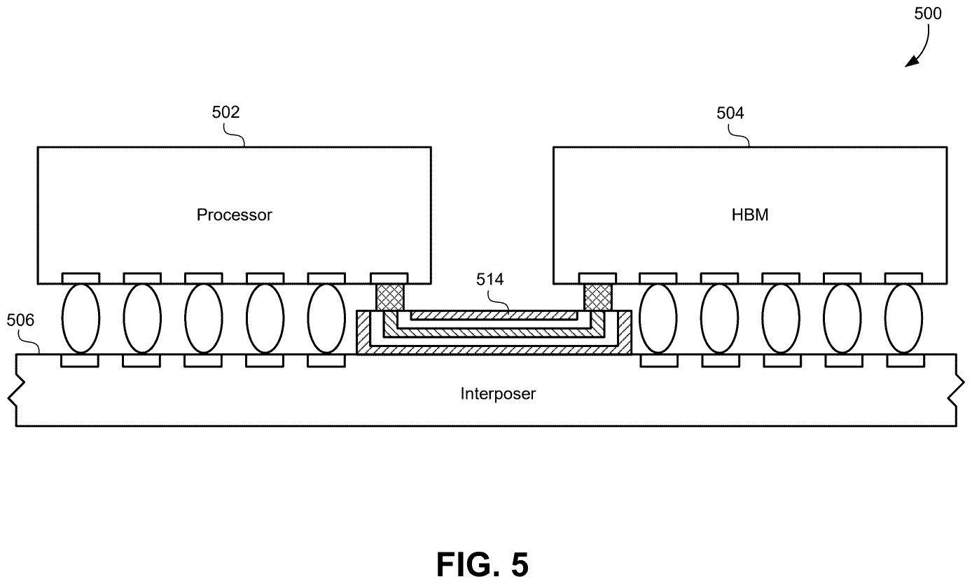

FIG. 5 illustrates a configuration where the coaxial bridge 514 sits on top of the interposer 506, according to some embodiments. Instead of forming a recess or cavity in the interposer 506 and inserting the coaxial bridge 514 into the cavity, some embodiments may instead allow the coaxial bridge 514 to sit on top of the interposer 506. The coaxial bridge 514 may be secured to the interposer 506 using epoxy or any other adhesive means. The coaxial bridge 514 may be mounted onto the interposer 506 before the dies are mounted to the interposer 506.

As described above in FIGS. 4A-4C, the coaxial bridge 514 may use hybrid bonding to connect to pads on the bottom side of a first die 502 and a second die 504. In order to accommodate the size of the coaxial bridge 514 without the cavity in the interposer 506, the coaxial bridge 514 may be manufactured to be thinner in the vertical direction. The overall height of the coaxial bridge 514 and/or the hybrid bonding interfaces on the coaxial bridge 514 may be determined by the space between the first die 502 and/or the second die 504 and the interposer 506. For example, the coaxial bridge 514 may first be mounted to the interposer 506, then the first die 502 and/or the second die 504 may be mounted to the interposer 506 and the coaxial bridge 514.

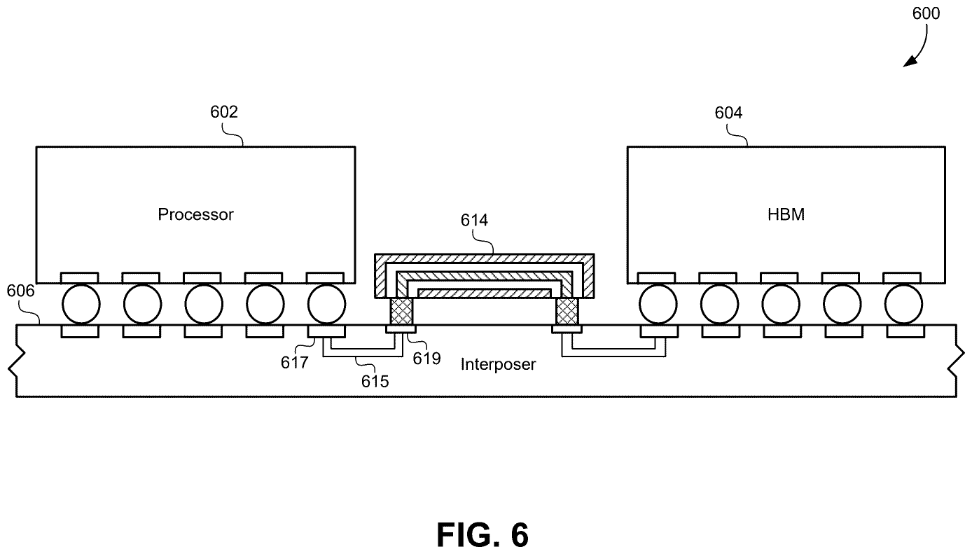

FIG. 6 illustrates a configuration where the coaxial bridge 614 may be inverted on the interposer 606, according to some embodiments. Instead of connecting directly to the pads on the underside of a first die 602 and/or a second die 604, the coaxial bridge 614 may be bonded directly to pads on the interposer 606. The orientation of the coaxial bridge 614 may be inverted compared to the configurations described above. Specifically, the hybrid bonding interfaces of the coaxial bridge 614 may be oriented downwards and may hybrid bond with pads on the interposer 606. This allows the coaxial bridge 614 to be mounted to the interposer 606 without being directly connected to the first die 602 and/or the second die 604, which may simplify the mounting process for these dies.

To form a conductive coupling with the pads on the bottom of the first die 602 and/or the second die 604, small traces may be extended between first pads 617 on the interposer 606 that bond with the pads on the dies, and between second pads 619 on the interposer 606 that bond with the coaxial bridge 614. The traces 615 on the interposer 606 may be referred to as “dog bone” traces, which are specialized trays designs for routing high-speed signals between connections on the interposer 606. For example, the traces 615 may include a narrow trace signal routed on the surface of the interposer 606 that extends from the first pads 617 to a widening pad or landing area for the second pads 619. Use of these dog bone traces still maintains a conductive coupling between the coaxial bridge 614 and the dies without requiring a direct connection between the interposer 606 and the coaxial bridge 614. Provided that these traces are small enough, the coaxial bridge 614 may allow for a significantly increased distance between the first die 602 and the second die 604, and may improve the speed and reliability of the communication between these dies. A “conductive coupling” may be considered forming at least part of a conductive path between the first die and the second die using the coaxial bridge where the resistance is less than 0.5 ohms. Alternatively, a direct coupling or direct connection may bond the interfaces of the coaxial bridge 614 directly to pads on these dies as illustrated in the previous examples.

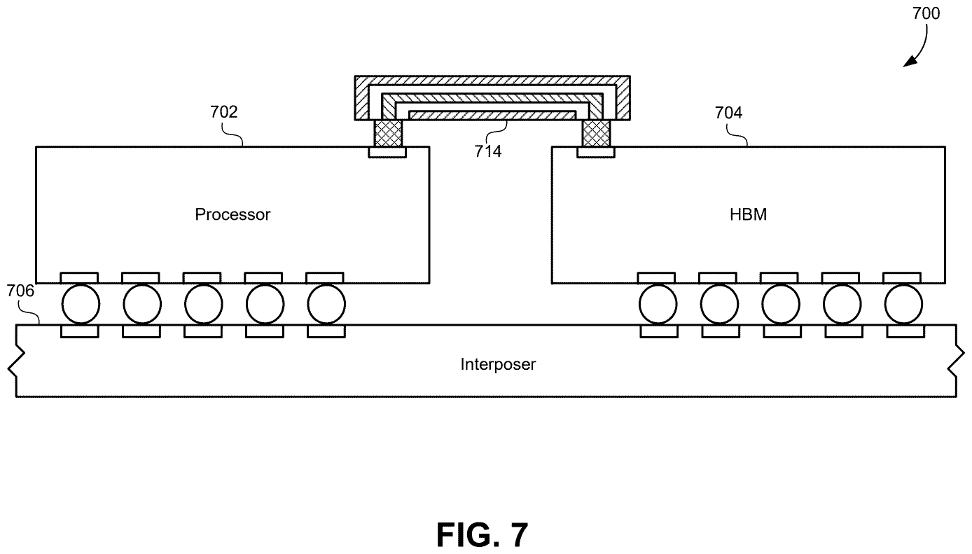

FIG. 7 illustrates a configuration where the coaxial bridge 714 is mounted on a top side of the dies, according to some embodiments. Note that the coaxial bridge 714 is compatible with other types of 2.5D or 3D electronic packaging assemblies. Therefore, the coaxial bridge 714 may be mounted to any pads on any die or substrate in the package. FIG. 7 illustrates an example of pads located on the top of the first die 702 and the second die 704 of an electronic assembly 700. The first die 702 and the second die 704 may be mounted to the interposer 706, and the coaxial bridge 714 may then be hybrid bonded or otherwise connected to the pads on top of these dies.

Although not shown explicitly, pads may also be located in other locations in the electronic packaging. For example, the coaxial bridge 714 may be installed in a vertical orientation to connect pads on an underlying substrate to pads on an overlaying substrate. This vertical orientation may place the hybrid bonding interfaces horizontally on the ends of the coaxial bridge rather than requiring the 90° turn illustrated in FIG. 7. Alternatively, the vertical orientation of the coaxial bridge 714 may be connected to pads on a top side of the first die 702 to pads on another die mounted to a bottom side of an overlaying interposer or substrate.

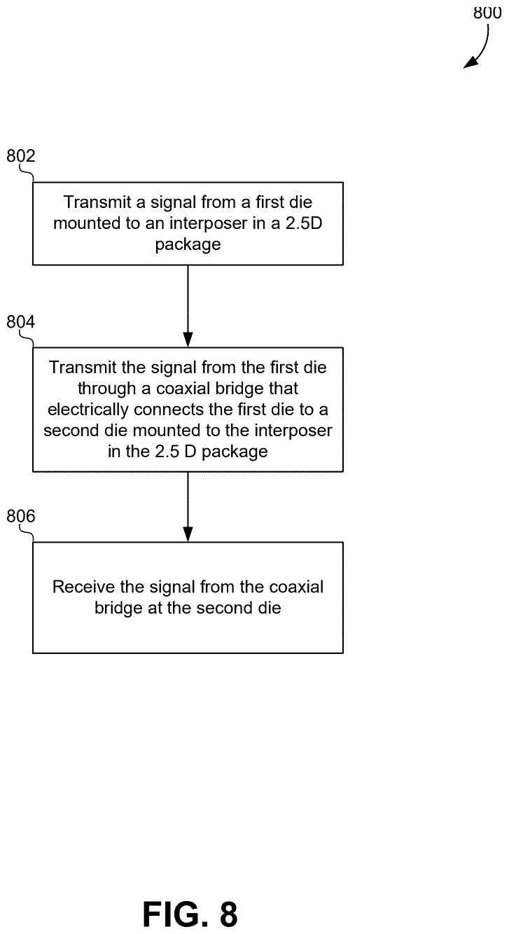

FIG. 8 illustrates a method 800 of transmitting signals between dies in a 2.5 D package, according to some embodiments. The method 800 may include transmitting a signal from a first die mounted to an interposer in a 2.5D package (802). This method may be carried out by any of the embodiments or configurations discussed herein using a coaxial bridge between two IC dies in electronic package. As a specific example, the first die may be mounted to an interposer in a 2.5D package as described above. The first die may include any IC, including a processor, an HBM, and so forth.

The method may also include transmitting the signal from the first die through a coaxial bridge that electrically connects the first die to a second die mounted on the interposer (804). The second die may also be a processor, an HBM, and/or any other high-speed IC. The electrical connection may include direct connections between the pads on the dies and the coaxial bridge, as well as indirect connections that run through additional components, such as the interposer.

The method may further include receiving the signal from the coaxial bridge at the second die (806). When transmitting high-speed signals through the coaxial bridge, the transmission rate may be considerably higher than other connection techniques through the interposer alone. Generally, as the frequency increases above 5 to 6 GHz, the majority of the insertion loss becomes conductor loss, mainly due to the skin effect. As the skin effect begins to take over in traditional conductors, the physical characteristics of the copper (surface roughness, etc.) begin to degrade the signal quality and reduce performance. The coaxial bridge solves this problem by using coaxial transmission lines that reduce interference between adjacent channels.

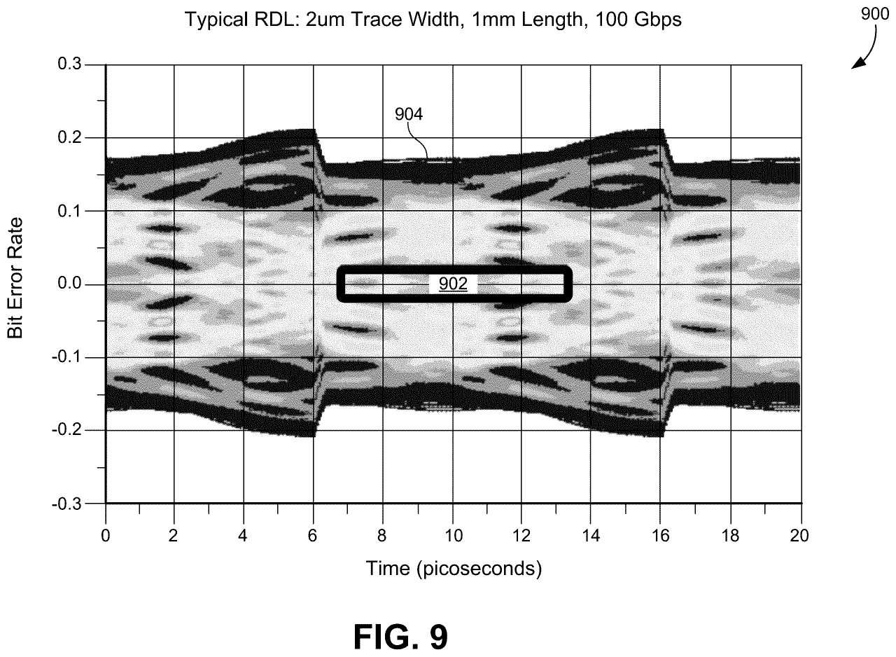

FIG. 9 illustrates a graph 900 that illustrates a bit error rate for a traditional RDL in an interposer. In this example, the copper traces on the interposer between the two dies are 2 μm wide and 1 mm long. When transmitting at speeds up to 100 Gb per second, the resulting bit error rate is shown in the graph 900. Specifically, as the bit level transition between 0 and 1, the transition is very noisy. An “eye mask” 902 is illustrated in the graph 900. In order for the signal to be clearly distinguished between the different bit levels, the eye mask 902 should be clear of any signal transitions. However, as illustrated in FIG. 9, the eye mask 902 is completely filled with signal transitions. In order to increase the transmission speeds up to 100 Gbps and beyond, wider traces need to be used, which would reduce the number of channels available per beach front millimeter on the dies.

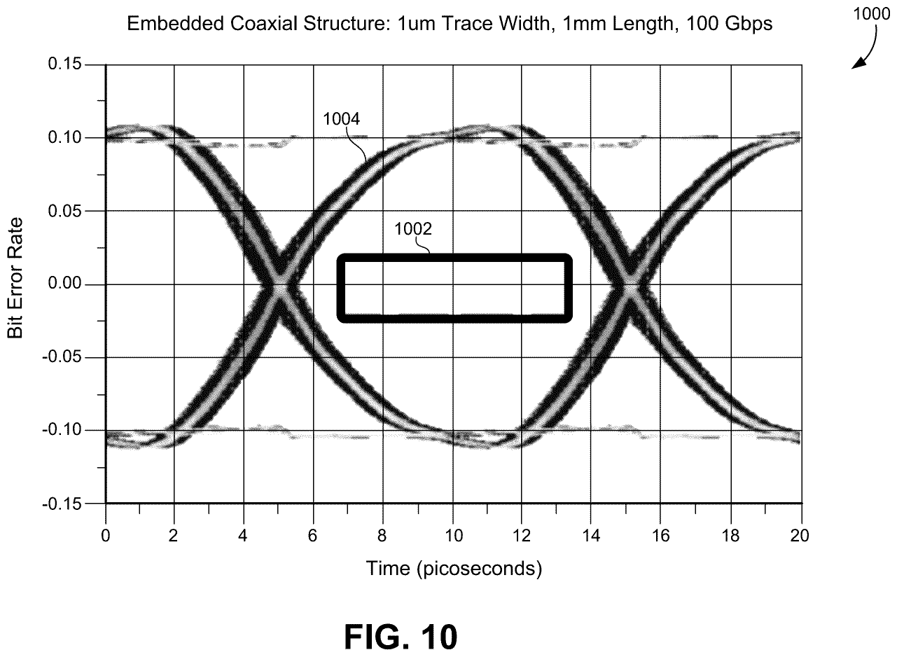

FIG. 10 illustrates a graph 1000 showing the same signal transmission using a coaxial bridge, according to some embodiments. In this example, the traces (i.e., the conductive cores in each of the coaxial transmission lines) have been reduced to 1 μm in width with the same distance of 1 mm. However, as illustrated by graph 1000, the signal transitions 1004 maintain a clean eye mask 1002, indicating that the signals can be transmitted with very little loss. This same level of signal integrity may be maintained at even longer lengths, up to 5 mm, 10 mm, 15 mm, and longer. This speed of 100 Gb is impossible to achieve with traditional traces through an RDL of an interposer.

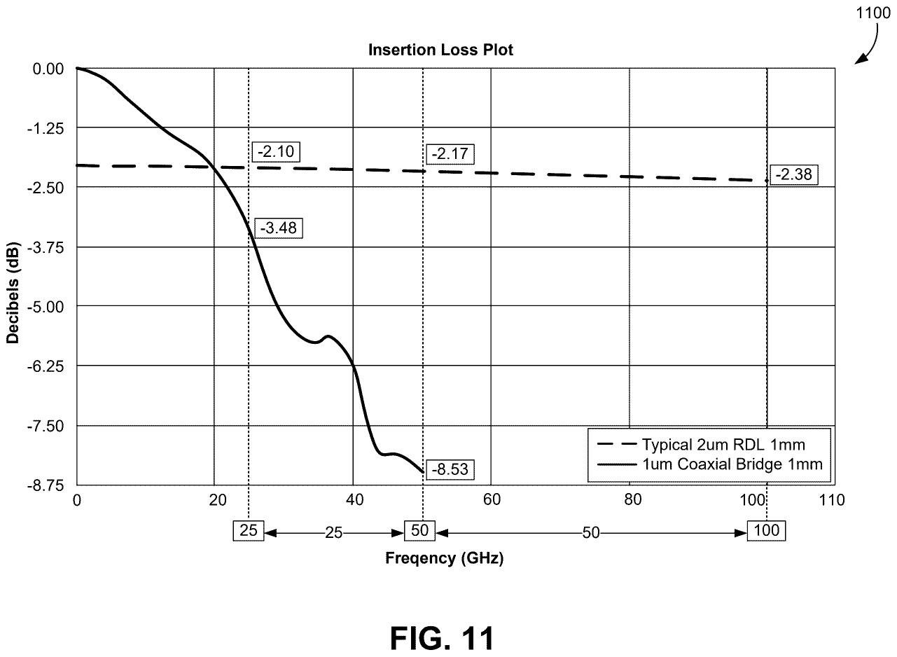

FIG. 11 illustrates a graph 1100 illustrating a comparison of the insertion loss at various frequencies using a typical 2 μm wide RDL and using a 1 μm wide coaxial bridge, both at a length of 1 mm. As illustrated in the graph 1100, the attenuation of the signal due to insertion loss using a typical RDL is greater than 8 dB. In comparison, the insertion loss using the thinner coaxial bridge is around 2.1 dB, providing better than double the performance. At 100 Gbps, the insertion loss of the coaxial bridge is still less than 2.4 dB, while the typical RDL is unusable.

Additionally, since the pitch of the coaxial transmission lines and the coaxial bridge can be relatively small (e.g., between about 6 μm and about 16 μm). The number of channels per millimeter of beach front area on the dies may be greatly increased. For example, the coaxial bridge may include between about 120 and about 150 single-ended channels per 1 mm of beachfront area on a die. This allows for greater than 50 Tbps/mm of space along the edge of the die, a signal density that is impossible in existing RDL communication traces.

As used herein, the terms “about” or “approximately” or “substantially” may be interpreted as being within a range that would be expected by one having ordinary skill in the art in light of the specification. By way of example, these terms may imply a 10% variation above or below a stated value (i.e., “approximately 50” would imply a range between 45 and 55).

In the foregoing description, for the purposes of explanation, numerous specific details were set forth in order to provide a thorough understanding of various embodiments. It will be apparent, however, that some embodiments may be practiced without some of these specific details. In other instances, well-known structures and devices are shown in block diagram form.

The foregoing description provides exemplary embodiments only, and is not intended to limit the scope, applicability, or configuration of the disclosure. Rather, the foregoing description of various embodiments will provide an enabling disclosure for implementing at least one embodiment. It should be understood that various changes may be made in the function and arrangement of elements without departing from the spirit and scope of some embodiments as set forth in the appended claims.

Specific details are given in the foregoing description to provide a thorough understanding of the embodiments. However, it will be understood that the embodiments may be practiced without these specific details. For example, circuits, systems, networks, processes, and other components may have been shown as components in block diagram form in order not to obscure the embodiments in unnecessary detail. In other instances, well-known circuits, processes, algorithms, structures, and techniques may have been shown without unnecessary detail in order to avoid obscuring the embodiments.

Also, it is noted that individual embodiments may have been described as a process which is depicted as a flowchart, a flow diagram, a data flow diagram, a structure diagram, or a block diagram. Although a flowchart may have described the operations as a sequential process, many of the operations can be performed in parallel or concurrently. In addition, the order of the operations may be re-arranged. A process is terminated when its operations are completed, but could have additional steps not included in a figure. A process may correspond to a method, a function, a procedure, a subroutine, a subprogram, etc. When a process corresponds to a function, its termination can correspond to a return of the function to the calling function or the main function.

The term “computer-readable medium” includes, but is not limited to portable or fixed storage devices, optical storage devices, wireless channels and various other mediums capable of storing, containing, or carrying instruction(s) and/or data. A code segment or machine-executable instructions may represent a procedure, a function, a subprogram, a program, a routine, a subroutine, a module, a software package, a class, or any combination of instructions, data structures, or program statements. A code segment may be coupled to another code segment or a hardware circuit by passing and/or receiving information, data, arguments, parameters, or memory contents. Information, arguments, parameters, data, etc., may be passed, forwarded, or transmitted via any suitable means including memory sharing, message passing, token passing, network transmission, etc.

Furthermore, embodiments may be implemented by hardware, software, firmware, middleware, microcode, hardware description languages, or any combination thereof. When implemented in software, firmware, middleware or microcode, the program code or code segments to perform the necessary tasks may be stored in a machine readable medium. A processor(s) may perform the necessary tasks.

In the foregoing specification, features are described with reference to specific embodiments thereof, but it should be recognized that not all embodiments are limited thereto. Various features and aspects of some embodiments may be used individually or jointly. Further, embodiments can be utilized in any number of environments and applications beyond those described herein without departing from the broader spirit and scope of the specification. The specification and drawings are, accordingly, to be regarded as illustrative rather than restrictive.

Additionally, for the purposes of illustration, methods were described in a particular order. It should be appreciated that in alternate embodiments, the methods may be performed in a different order than that described. It should also be appreciated that the methods described above may be performed by hardware components or may be embodied in sequences of machine-executable instructions, which may be used to cause a machine, such as a general-purpose or special-purpose processor or logic circuits programmed with the instructions to perform the methods. These machine-executable instructions may be stored on one or more machine readable mediums, such as CD-ROMs or other type of optical disks, floppy diskettes, ROMs, RAMs, EPROMs, EEPROMs, magnetic or optical cards, flash memory, or other types of machine-readable mediums suitable for storing electronic instructions. Alternatively, the methods may be performed by a combination of hardware and software.

What is claimed is:

1. An electronic assembly comprising:
an interposer;
a first die mounted on the interposer;
a second die in the electronic assembly; and
a coaxial bridge that conductively couples the first die and the second die.

2. The electronic assembly of claim 1, wherein the second die is mounted on the interposer adjacent to the first die, and the coaxial bridge is oriented horizontally in the electronic assembly.

3. The electronic assembly of claim 1, wherein the second die is mounted vertically above the first die in the electronic assembly, and the coaxial bridge is oriented vertically in the electronic assembly.

4. The electronic assembly of claim 1, wherein the coaxial bridge is mounted to the interposer.

5. The electronic assembly of claim 4, wherein the coaxial bridge is mounted to a surface of the interposer.

6. The electronic assembly of claim 4, wherein the interposer comprises a cavity that extends between the first die and the second die and below a surface of the interposer, and the coaxial bridge is mounted in the cavity.

7. The electronic assembly of claim 1, wherein the coaxial bridge is connected directly to pads on bottom surfaces of the first die and the second die through a hybrid bonding interface.

8. The electronic assembly of claim 1, wherein the coaxial bridge is connected directly to pads on a surface of the interposer.

9. The electronic assembly of claim 1, wherein the coaxial bridge comprises a rigid, modular structure comprising a plurality of individual coaxial transmission lines.

10. A coaxial bridge for a 2.5D package, the coaxial bridge comprising:
a plurality of coaxial transmission lines, wherein each of the plurality of coaxial transmission lines comprises:
a conductive core;
a dielectric material encasing the conductive core;
a conductive coaxial enclosure encasing the dielectric material; and
a pair of hybrid bonding interfaces that are conductively coupled to ends of the conductive core;
wherein the plurality of coaxial transmission lines are packaged together in a single modular unit.

11. The coaxial bridge of claim 10, wherein the coaxial bridge comprises a length of between about 5 mm and about 15 mm.

12. The coaxial bridge of claim 10, wherein each conductive core is between about 0.5 μm and about 1.5 μm wide.

13. The coaxial bridge of claim 10, wherein a pitch of the plurality of coaxial transmission lines is between about 6 μm and about 16 μm.

14. The coaxial bridge of claim 10, wherein each of the plurality of coaxial transmission lines comprises a width of between about 2.5 μm and about 7.5 μm.

15. The coaxial bridge of claim 10, wherein the conductive core comprises a metal, the dielectric material comprises a material with a dielectric constant less than about 2.5 at 1 MHz, and the conductive coaxial enclosure comprises a metal.

16. A method of transmitting signals between dies in a 2.5D package, the method comprising:
transmitting a signal from a first die mounted to an interposer in the 2.5D package;
transmitting the signal from the first die through a coaxial bridge that electrically connects the first die to a second die mounted to the interposer in the 2.5 D package; and
receiving the signal from the coaxial bridge at the second die.

17. The method of claim 16, wherein a transmission rate through a single coaxial transmission line in the coaxial bridge is greater than about 75 Gbps.

18. The method of claim 16, wherein a transmission rate through the coaxial bridge is greater than about 50 Tbps/mm of space along an edge of the first die.

19. The method of claim 16, wherein the signal comprises contents of a memory location in a high-bandwidth memory (HBM) of the second die.

20. The method of claim 16, wherein the coaxial bridge comprises greater than about 100 channels per millimeter of space along an edge of the first die.
